(19) United States
(12) Patent Application Publication
(10) Pub. No.: US 2024/0178141 A1
(43) Pub. Date: May 30, 2024

(54) NANOMOLDING OF ELECTRICAL INTERCONNECTS

(71) Applicant: Cornell University, Ithaca, NY (US)

(72) Inventors: Mehrdad Kiani, Ithaca, NY (US); Jeeyoung Cha, Ithaca, IN (US)

(21) Appl. No.: 18/521,864

(22) Filed: Nov. 28, 2023

Related U.S. Application Data
(60) Provisional application No. 63/428,280, filed on Nov. 28, 2022.

(51) Int. Cl. H01L 23/528; H01L 21/768; H01L 23/532

(52) U.S. Cl. CPC H01L 23/5283; H01L 21/76828; H01L 23/53228

(57) ABSTRACT

A method for forming semiconductor interconnects includes establishing a nanostructure in a substrate. The nanostructure may be embodied as a trench or other structure that extends from a first semiconductor device or structure to a second semiconductor device or structure. The method also includes establishing an electrically conductive material, such as a polycrystalline or single crystal copper material, on the substrate over the nanostructure to form a semiconductor assembly. The semiconductor assembly is then subjected to thermal process that causes the electrically conductive material to mold into the nanostructure established in the substrate to form an electrical interconnect that electrically connects the first semiconductor structure to the second semiconductor structure.

The present application claims priority to, and the benefit of, U.S. Patent Application Ser. No. 63/428,280, entitled “NANOMOLDING OF ELECTRICAL INTERCONNECTS” by Mehrdad Kiani et al., which was filed on Nov. 28, 2022, the entirety of which is incorporated herein by reference.

### FIELD OF THE DISCLOSURE

The present disclosure relates generally to the formation of nanostructure and, more particularly, to the formation of nanostructure interconnects capable of electrically connecting semiconductor devices.

### BACKGROUND

Interconnects are electrical structures that electrically connect two or more semiconductor devices or structures (e.g., transistors) in an electrical circuit or device such as an integrated circuit. The historical direction of the electrical device industry is for the production of smaller and more efficient electrical circuits and devices. However, as the overall footprint of electrical devices shrink, the corresponding size of interconnects included in such electrical devices likewise shrink. The shrinking of interconnects, however, offer challenges in the design and fabrication of electrical components because interconnects can be the limiting consideration in operational speed and efficiency of the resulting electrical component.

The reduction of the size of interconnects in electrical circuits is resulting in the need for nano-scale interconnects. However, while the ability to fabricate complex nanostructures is increasingly researched, a nanofabrication approach that enables simultaneous control over crystallinity, size, morphology, and material composition appears to remain elusive. For example, while bottom-up techniques such as molecular beam epitaxy and atomic layer deposition can fabricate high quality single crystalline films and coatings, those techniques are generally not useful in the fabrication of other more complex nanostructures. Additionally, those techniques do not readily translate to different material classes, require extensive optimization for each material composition of interest, and control of grain size and orientation is limited or dictated by the underlying substrate. Colloidal synthesis techniques can achieve acceptable size, shape, and composition control but are generally limited to 0D or 1D nanostructures, requires surface ligands to stabilize in solution, and cannot be easily integrated with other nanofabrication techniques or cleanroom processing. Micro-additive manufacturing, such as two-photon lithography or electrohydrodynamic redox 3D printing, enables arbitrary control of morphology and rapid optimization but is generally limited to a few material classes, cannot be performed over large areas due to the limitations of the rastering of a laser or a tip, and the final structures are nanoporous. Additionally, while top-down techniques, such as lithography, can enable control of morphology and size, those techniques are limited in material choice and lack control of crystallinity.

Thermomechanical nanomolding (TMNM) is a technique in which a bulk feedstock of a desired material is pressed through a nanoporous mold at elevated temperatures and pressures. TMNM has been shown to yield high aspect ratio single crystal nanowires over wafer-scale distances and to be rather material-agnostic. However, while TMNM can be used to form nanowires of a desired material, it is unclear whether TMNM techniques can be used to form more complex nanostructures, such as those required in an electrical circuit or device, which may have different boundary conditions and surface area to volume ratios, and if additional growth mechanisms are at play.

### SUMMARY

According to an aspect of the present disclosure, a method for forming semiconductor interconnects may include establishing a nanostructure in a substrate and establishing an electrically conductive material on the substrate over the nanostructure to form a semiconductor assembly. The nanostructure may extend from a first semiconductor structure of the substrate to a second semiconductor structure of the substrate. The method may also include performing a thermal process on the semiconductor assembly that causes the electrically conductive material to mold into the nanostructure established in the substrate to form an electrical interconnect that electrically connects the first semiconductor structure to the second semiconductor structure.

In some embodiments, the nanostructure may be embodied as a trench formed in the substrate. In such embodiments, the trench may have at least one dimension that is less than 100 nanometers. Additionally, in some embodiments, the trench may have an aspect ratio of a height of the trench to a width of the trench of at least 10.

In some embodiments, establishing the nanostructure in the substrate may include establishing the nanostructure in a silicon substrate, an oxide layer, or a dielectric layer. Additionally, in some embodiments, the first semiconductor structure may be embodied as a first semiconductor transistor and the second semiconductor structure may be embodied as a second semiconductor transistor. In such embodiments, establishing the nanostructure in the substrate may include establishing the nanostructure to extend from the first semiconductor transistor to the second semiconductor transistor.

Additionally, in some embodiments, establishing the electrically conductive material on the substrate over the nanostructure may include establishing a single crystal copper layer on the substrate over the nanostructure. Alternatively, in other embodiments, establishing the electrically conductive material on the substrate over the nanostructure may include establishing a polycrystalline copper layer on the substrate over the nanostructure.

In some embodiments, the nanostructure may be embodied as a trench formed in the substrate, and the trench may include an inner wall. In such embodiments, establishing the electrically conductive material on the substrate may include aligning the electrically conductive material with the inner wall of the trench. For example, in some embodiments, aligning the electrically conductive material with the inner wall of the trench may include aligning a crystallographic plane of the electrically conductive material that has the lowest surface energy parallel to the inner wall of the trench. In some embodiments, the electrically conductive material may be embodied as a single crystal copper material and, in such embodiments, aligning the electrically conductive material with the inner wall of the trench may include aligning the (111) crystallographic plane of the single crystal copper material parallel to the inner wall of the trench. Alternatively, in other embodiments, the electrically conductive material may be embodied as a Body Centered Cubic (BCC) structured material and, in such embodiments, aligning the electrically conductive material with the inner wall of the trench may include aligning the (110) crystallographic plane of the BCC structured material parallel to the inner wall of the trench. Alternatively, in yet other embodiments, the electrically conductive material may be embodied as a Hexagonal Close Packed (HCP) structured material and, in such embodiments, aligning the electrically conductive material with the inner wall of the trench may include aligning the (001) crystallographic plane of the HCP structured material parallel to the inner wall of the trench.

Additionally, in some embodiments, performing the thermal process may include heating the semiconductor assembly to a melting temperature (Tm) of the electrically conductive material of in the range of 0.4 Tm to 0.7 Tm at a pressure in the range of 20 MegaPascals (MPa) to 100 MPa for a time period in the range of 1 hour to 2 hours. For example, in some embodiments, the electrically conductive material may be embodied as a nanocrystalline copper material and, in such embodiments, the performing the thermal process may include heating the semiconductor assembly to a temperature of 400 degrees Celsius at a pressure of 30 MPa for a time period of about 90 minutes. In other embodiments, the electrically conductive material may be embodied as a microcrystalline copper material and, in such embodiments, performing the thermal process may include heating the semiconductor assembly to a temperature of 400 degrees Celsius at a pressure of 60 MPa for a time period of about 90 minutes. In yet other embodiments, the electrically conductive material may include a single crystal copper material and, in such embodiments, performing the thermal process may include heating the semiconductor assembly to a temperature of 400 degrees Celsius at a pressure of 70 MPa for a time period of about 90 minutes.

In some embodiments, the method may also include lining the nanostructure with a barrier material prior to establishing the electrically conductive material on the substrate. In such embodiments, the barrier material may limit the interaction of the electrically conductive material and the substrate. For example, the barrier material may be a nitride material, such as tantalum nitride or other material that limits the interaction of the electrically conductive material and the substrate.

According to another aspect of the present disclosure, an electrical circuit may include a first semiconductor device established in a substrate and a second semiconductor device established in the substrate. The electrical circuit may also include a two-dimensional nanostructure interconnect that electrically connects the first semiconductor device to the second semiconductor device. In some embodiments, the two-dimensional nanostructure interconnect may be embodied as a single crystal copper interconnect formed in a trench of the substrate having a width less than 100 nanometers and an aspect ratio of a height of the trench to the width of the trench of at least 10.

According to a further aspect of the present disclosure, a method for forming semiconductor interconnects may include forming a nanostructure in a substrate and depositing an electrically conductive material onto the substrate over the nanostructure. The nanostructure may extend from a first semiconductor structure of the substrate to a second semiconductor structure of the substrate. The method may also include performing a thermal process on the substrate and electrically conductive material to cause the electrically conductive material to mold into the nanostructure formed in the substrate to form an interconnect electrically connecting the first semiconductor structure to the second semiconductor structure.

In some embodiments, the nanostructure may be embodied as a trench formed in the substrate. Alternatively, in other embodiments, the nanostructure may be embodied as a hole, via, or cavity formed in the substrate. In some embodiments, the nanostructure may have at least one dimension that is less than 100 nanometers. Additionally, the nanostructure may have a height-to-width aspect ratio of at least 10 and/or a length-to-width and/or a length-to-height aspect ratio of at least 1000.

Additionally, in some embodiments, the substrate may be embodied as a silicon substrate. Alternatively in other embodiments, the substrate may be embodied as an oxide layer or a dielectric layer. For example, in some embodiments, the substrate may be embodied as aluminum oxide layer or a silicon dioxide layer, and the nanostructure may be formed in the aluminum oxide layer or the silicon dioxide layer.

In some embodiments, the first and second semiconductor structures may be embodied as semiconductor devices. For example, the first and second semiconductor structures may be embodied as transistors. Alternatively, in other embodiments, the first and second semiconductor structures may be embodied as conductive contact pads formed on the substrate.

Additionally, in some embodiments, the electrically conductive material may be embodied a copper material, a cobalt material, or a ruthenium material. For example, the electrically conductive material may be embodied as a material selected from the group consisting of CoSn, Al₂Cu, CoSi, and MoP.

In some embodiments, depositing the electrically conductive material onto the substrate may include growing a film of the electrically conductive material on the substrate over the nanostructure. Additionally, in some embodiments, the interconnect may be embodied as a single crystal. For example, the interconnect may consist of a single crystal. Alternatively, in other embodiments, the electrically conductive material may be embodied as a polycrystalline material. For example, the electrically conductive material may be embodied as polycrystalline copper.

In some embodiments, the nanostructure may be embodied as a trench formed in the substrate, and the trench may include an inner wall. In such embodiments, depositing the electrically conductive material onto the substrate may include aligning the electrically conductive material with the inner wall of the trench. For example, in such embodiments, aligning the electrically conductive material with the inner wall of the trench may include aligning a crystallographic plane of the electrically conductive material that has the lowest surface energy parallel to the inner wall of the trench.

In some embodiments, the electrically conductive material may be embodied as a Body Centered Cubic (BCC) structured material. In such embodiments, aligning the electrically conductive material with the inner wall of the trench may include aligning the (110) crystallographic plane of the BCC structured material parallel to the inner wall of the trench. In other embodiments, the electrically conductive material may be embodied as a Hexagonal Close Packed (HCP) structured material. In such embodiments, aligning the electrically conductive material with the inner wall of the trench may include aligning the (001) crystallographic plane of the HCP structured material parallel to the inner wall of the trench. Alternatively, in yet other embodiments, the electrically conductive material may be embodied as a single crystal copper material. In such embodiments, aligning the electrically conductive material with the inner wall of the trench comprises may include the (111) crystallographic plane of the single crystal copper material parallel to the inner wall of the trench.

Additionally, in some embodiments, performing the thermal process may include heating the substrate to a melting temperature (Tm) of the electrically conductive material of in the range of 0.4 Tm to 0.7 Tm at a pressure in the range of 20 MegaPascals (MPa) to 200 MPa for a time period in the range of 1 hour to 2 hours. For example, performing the thermal process may include heating the substrate to 0.5 Tm. In some embodiments, the electrically conductive material may be embodied as a copper material and, in such embodiments, performing the thermal process may include heating the substrate to about 450 degrees Celsius. In some embodiments, performing the thermal process may include exposing the substrate to a pressure in the range of about 30 MPa to 60 MPa. Additionally or alternatively, in some embodiments, performing the thermal process may include heating the substrate to a primer melting temperature (Tm) of the electrically conductive material of in the range of 0.4 Tm to 0.7 Tm. Additionally or alternatively, in some embodiments, performing the thermal process may include exposing the substrate to a pressure in the range of 20 MegaPascals (MPa) to 200 MPa.

In some embodiments, the method may further include lining the nanostructure with a barrier material prior to depositing the electrically conductive material onto the substrate. The barrier material may be selected so as to limit interaction of the electrically conductive material and the substrate. For example, the barrier material may be embodied as a metallic material. Additionally, the method may include forming one or more liner layers. In such embodiments, the one or more liner layers may be embodied as a first liner layer on the first semiconductor structure of the substrate and a second liner layer on the second semiconductor structure of the substrate. The one or more liner layers may be selected from materials, for example, comprising a nitride material (e.g., tantalum nitride), silicon dioxide, metallic materials (e.g. silver, lanthanum, titanium, ruthenium, iridium, tungsten, zirconium, antimony, calcium, any combination or alloy thereof), metal oxide materials, or metal nitride materials.

Additionally, in some embodiments, the substrate may be embodied as or otherwise include one or more dielectric materials. Additionally, in some embodiments, the method may include aligning a type of planes of a single crystal of the electrically conductive material to one or more walls of the mold. Alternatively or additionally, in some embodiments, the method may further include forming one or more interconnects each comprising a single crystal material.

According to yet a further aspect of the present disclosure, a semiconductor device may include a substrate, a first semiconductor structure formed on the substrate, a second semiconductor structure formed on the substrate, and a nanostructure formed in the substrate. The nanostructure may be embodied as a trench that extends from the first semiconductor structure to the second semiconductor structure. The semiconductor device may also include electrically conductive material molded into the nanostructure using any one of the methods described above such that the electrically conductive material electrically connects the first semiconductor structure to the second semiconductor structure.

Accordingly to still a further aspect of the present disclosure, a method for forming semiconductor interconnects may include forming a nanostructure in a substrate extending from a first surface of the substrate to a second surface of the substrate, depositing an electrically conductive material over the nanostructure to form a barrier layer over the nanostructure, and nanomolding an electrically conductive material into the nanostructure to cause the electrically conductive material to form a single crystal interconnect electrically connecting the first surface of the substrate to the second surface of the substrate.

In some embodiments, the nanostructure may be embodied as a trench, a hole, via or a cavity. Additionally, in some embodiments, the nanostructure may have at least one dimension that is less than 100 nanometers. For example, the nanostructure may have a height-to-width aspect ratio of at least 10 and/or a length-to-width and/or a length-to-height aspect ratio of at least 1000. Additionally, in some embodiments, the substrate may be embodied as a silicon substrate, a silicon dioxide substrate, or an aluminum oxide substrate.

In some embodiments, wherein the substrate includes a first semiconductor structure on the first surface of the substrate and a second semiconductor structure on the second surface of the substrate. In such embodiments, the single crystal interconnect may electrically connecting the first semiconductor structure to the second semiconductor structure. For example, the first semiconductor structure may be embodied as a transistor, contact pad, or conductive element, and the second semiconductor structure may be embodied as a transistor, contact pad, or conductive element. In some embodiments, the interconnect may be formed from copper, cobalt, ruthenium, CoSn, Al₂Cu, CoSi, or MoP. For example, in some embodiments, the interconnect may consist of copper, cobalt, ruthenium, CoSn, Al₂Cu, CoSi, or MoP.

In some embodiments, the nanostructure may be embodied as a trench defining an inner wall extending in a first direction. In such embodiments, nanomolding of the electrically conductive material into the nanostructure to form the single crystal interconnect may align an orientation of a crystallographic plane of the interconnect to the first direction of the trench wall. For example, in some embodiments, the crystallographic plane of the interconnect may be embodied as a (111) crystallographic plane, a (110) crystallographic plane, or a (001) crystallographic plane.

Additionally, in some embodiments, nanomolding the electrically conductive material may include heating the substrate to a melting temperature (Tm) of the electrically conductive material, in the range of 0.4 Tm to 0.7 Tm, at a pressure in the range of 20 MegaPascals (MPa) to 200 MPa, and for a time period between about 1 hour to about 2 hours. For example, heating the substrate may include heating the substrate to 0.5 Tm or about 450 degrees Celsius. Additionally, in some embodiments, the nanomolding may be performed at an elevated pressure between about 30 MPa to about 60 MPa. Additionally or alternatively, the nanomolding may include heating the substrate to a primer melting temperature (Tm) of the electrically conductive material in the range of 0.4 Tm to 0.7 Tm. Additionally or alternatively, the nanomolding may be performed at a pressure in the range of 20 MegaPascals (MPa) to 200 MPa. Furthermore, in some embodiments, the electrically conductive material into the nanostructure may cause the electrically conductive material to form a plurality of single crystal interconnects electrically connecting the first surface of the substrate to the second surface of the substrate.

According to yet another aspect of the present disclosure, a method for forming semiconductor interconnects may include forming a nanostructure in a substrate extending from a first surface of the substrate to a second surface of the substrate, depositing an electrically conductive material over the nanostructure to form a barrier layer over the nanostructure; and disposing within the nanostructure a nanomolded single crystal interconnect to electrically connect the first surface of the substrate to the second surface of the substrate. In some embodiments, the forming of the nanostructure in the substrate may include forming a plurality of nanostructures extending from the first surface of the substrate to the second surface of the substrate. In such embodiments, depositing of the electrically conductive material may include depositing of the electrically conductive material over the plurality of nanostructures to form a barrier layer over each of the plurality of nanostructures. Additionally, in such embodiments, disposing of the nanomolded single crystal may include disposing a nanomolded single crystal within each of the plurality of nanostructures to electrically connect the first surface of the substrate to the second surface of the substrate.

### BRIEF DESCRIPTION OF THE DISCLOSURE

The concepts described herein are illustrated by way of example and not by way of limitation in the accompanying figures. For simplicity and clarity of illustration, elements illustrated in the figures are not necessarily drawn to scale. Where considered appropriate, reference labels have been repeated among the figures to indicate corresponding or analogous elements.

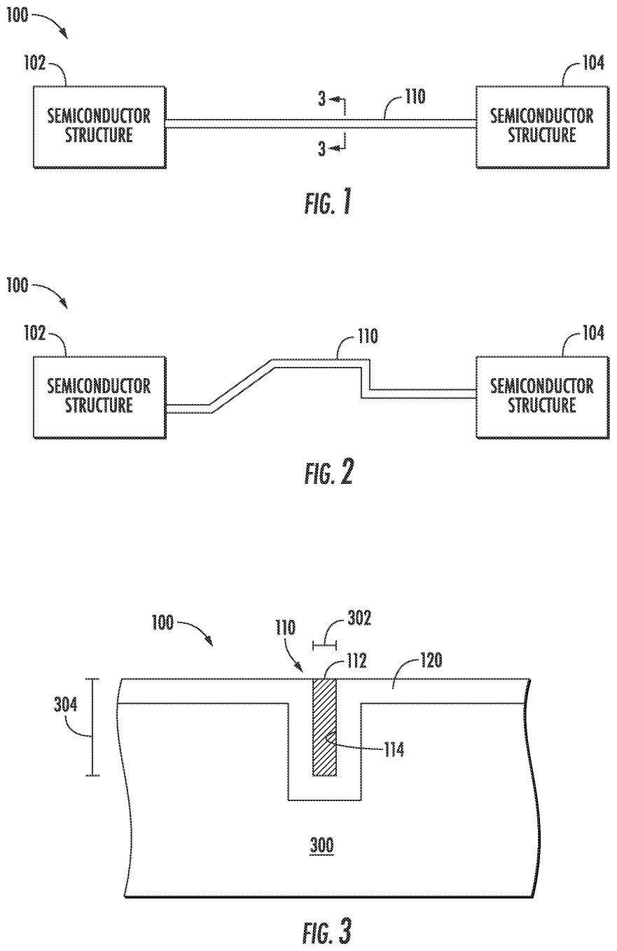

FIG. 1 is a simplified diagram of an embodiment of an electrical circuit including a nanostructure interconnect that electrically connects two semiconductor structures, such as transistors;

FIG. 2 is a simplified diagram of another embodiment of the electrical circuit of FIG. 1 including a nanostructure interconnect having a complex routing path;

FIG. 3 is a cross-sectional view of the nanostructure interconnect of FIG. 1 taken generally along the section line 3-3 of FIG. 1;

FIG. 4 is a simplified diagram of an embodiment of another electrical circuit including nanostructure interconnects that electrically connects multiple semiconductor structures, which are embodied as buried structures in a substrate;

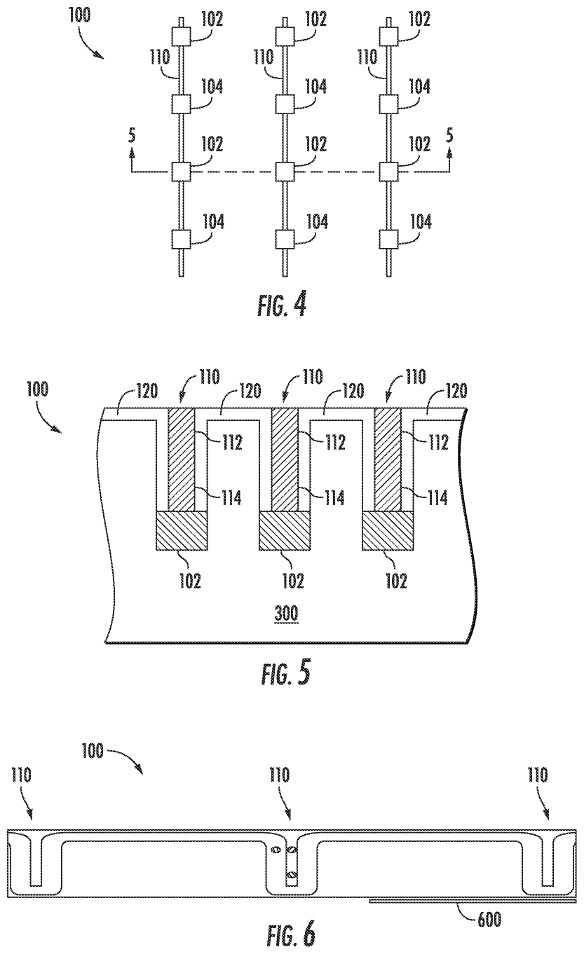

FIG. 5 is a cross-sectional view of the nanostructure interconnects of FIG. 4 taken generally along section line 5-5 of FIG. 4;

FIG. 6 is an illustration of an illustrative cross-sectional Scanning Transmission Electron Microscopy (STEM) imaging of a nanocrystalline copper interconnect formed in a corresponding nanostructure (trench) similar to the nanostructure interconnect of FIGS. 4 and 5;

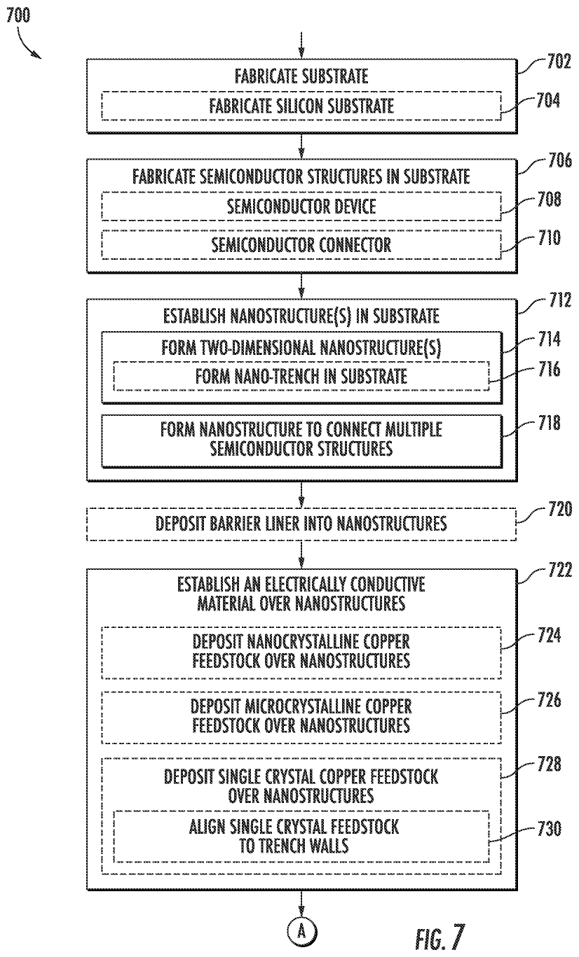

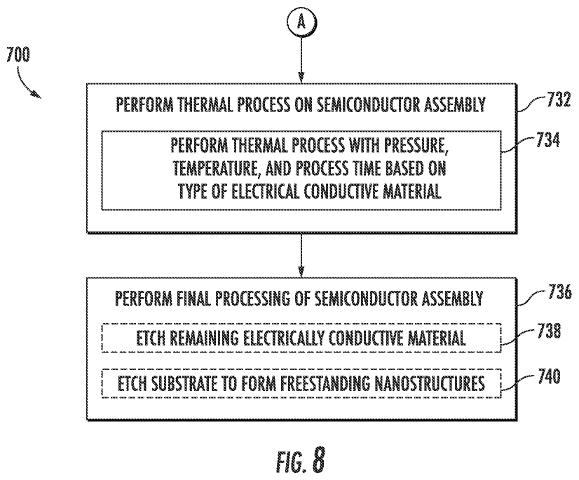

FIGS. 7 and 8 are a simplified flow chart of a method for forming semiconductor interconnects;

FIG. 9 is a simplified illustration of a substrate which may be fabricated during the performance of the method of FIGS. 7 and 8;

FIG. 10 is a simplified illustration of a semiconductor device including the substrate of FIG. 9 having a semiconductor formed therein/thereon, which may be fabricated during the performance of the method of FIGS. 7 and 8;

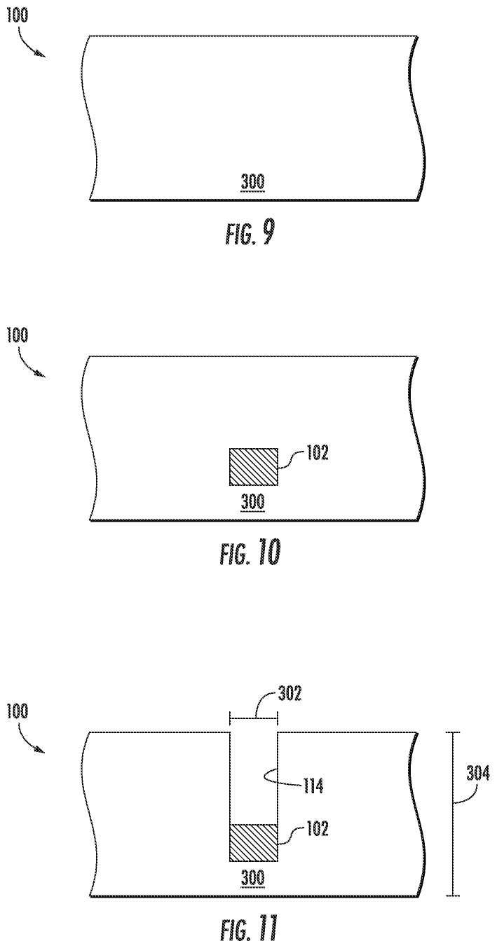

FIG. 11 is a simplified illustration of the semiconductor device of FIG. 10 including a nanostructure (illustratively, a trench) formed in the substrate, which may be established during the performance of the method of FIGS. 7 and 8;

FIG. 12 is a simplified illustration of the semiconductor device of FIG. 11 including a barrier liner or layer deposited into the nanostructure, which may formed during the performance of the method of FIGS. 7 and 8;

FIG. 13 is an illustrative perspective cross-sectional STEM imaging of a set of nanostructure trenches formed in a substrate and including a barrier liner deposited in the nanostructure trench similar to the semiconductor device of FIG. 12;

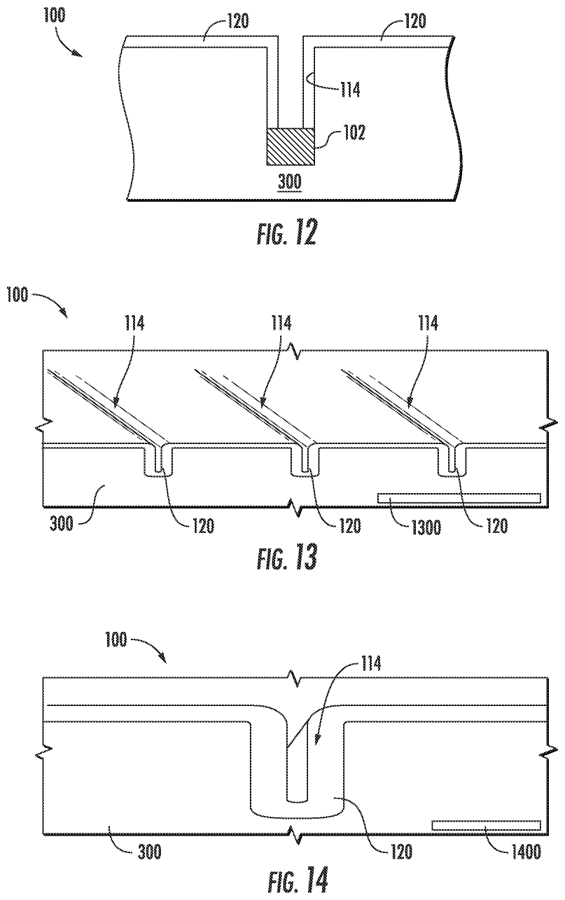

FIG. 14 is another illustrative perspective cross-sectional STEM imaging of a nanostructure trench of the set of nanostructure trenches of FIG. 13;

FIG. 15 is a simplified illustration of the semiconductor device of FIG. 12 including an electrically conductive material formed on the substrate and over the nanostructure, which may be established during the performance of the method of FIGS. 7 and 8;

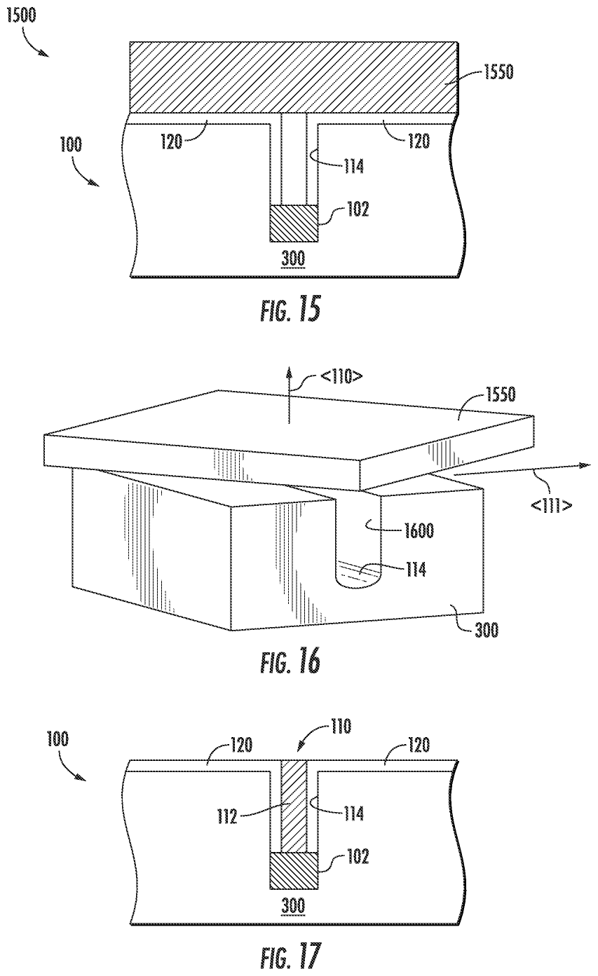

FIG. 16 is a simplified illustration of a crystallographic plane of the electrically conductive material of FIG. 15 being aligned with an inner wall of a nanostructure trench, which may be performed during the performance of the method of FIGS. 7 and 8;

FIG. 17 is a simplified illustration of the semiconductor device of FIG. 15 subsequent to a thermal process and an optional final processing, which may be performed during the performance of the method of FIGS. 7 and 8;

FIG. 18 is a graphical illustration of a 4D-STEM grain orientation map of illustrative nanocrystalline copper interconnects formed in corresponding nanostructure trenches;

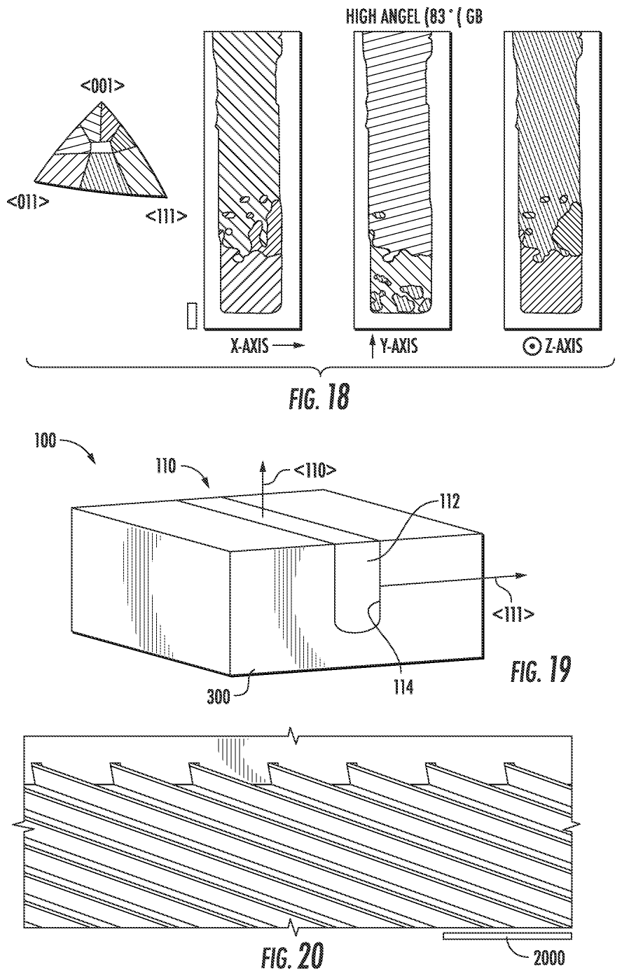

FIG. 19 is a simplified illustration of a nanostructure trench filled with a single crystal copper nanostructure interconnect and having the (111) crystallographic plane of the nanostructure interconnect aligned with an inner wall of the trench;

FIG. 20 is an illustrative perspective “false color” SEM image of a set of single crystal copper nanofins, which may be formed using the method of FIGS. 7 and 8;

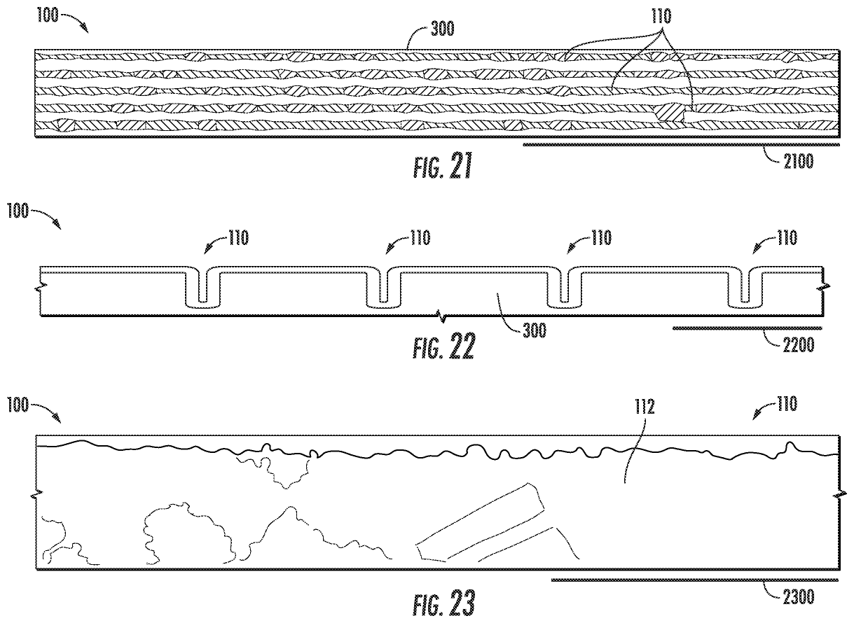

FIG. 21 is a simplified diagram of an illustrative Optical Bright Field Image of a set of nanostructure trenches formed in a substrate with each trench including a corresponding nanocrystalline copper interconnect formed therein, which may be fabricated by the method of FIGS. 7 and 8;

FIG. 22 is a simplified diagram of an illustrative cross-sectional Scanning Electron Microscopy (SEM) imaging of the set of nanostructure trenches and corresponding nanocrystalline copper interconnects of FIG. 21;

FIG. 23 is a simplified diagram of an illustrative longitudinal cross-sectional SEM imaging of a nanostructure trench and corresponding nanocrystalline copper interconnect of FIG. 21;

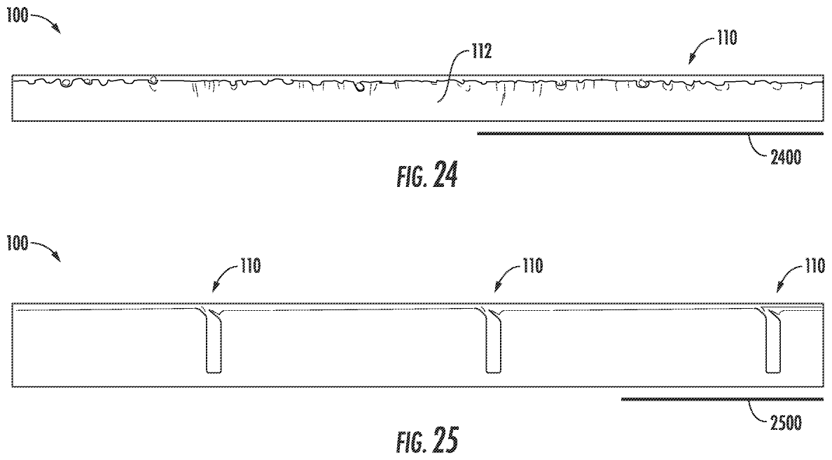

FIG. 24 is a simplified diagram of an illustrative longitudinal cross-sectional SEM imaging of a nanostructure trench having a microcrystalline copper interconnect formed therein; and

FIG. 25 is a simplified diagram of an illustrative cross-sectional STEM imaging of a set of nanostructure trenches having corresponding single crystal copper interconnects formed therein.

### DETAILED DESCRIPTION

While the concepts of the present disclosure are susceptible to various modifications and alternative forms, specific embodiments thereof have been shown by way of example in the drawings and will be described herein in detail. It should be understood, however, that there is no intent to limit the concepts of the present disclosure to the particular forms disclosed, but on the contrary, the intention is to cover all modifications, equivalents, and alternatives consistent with the present disclosure and the appended claims.

References in the specification to “one embodiment.” “an embodiment,” “an illustrative embodiment,” etc., indicate that the embodiment described may include a particular feature, structure, or characteristic, but every embodiment may or may not necessarily include that particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to effect such feature, structure, or characteristic in connection with other embodiments whether or not explicitly described. Additionally, it should be appreciated that items included in a list in the form of “at least one A, B, and C” can mean (A); (B); (C): (A and B); (B and C); or (A, B, and C). Similarly, items listed in the form of “at least one of A, B, or C” can mean (A); (B); (C): (A and B); (B and C); or (A, B, and C).

In the drawings, some structural or method features may be shown in specific arrangements and/or orderings. However, it should be appreciated that such specific arrangements and/or orderings may not be required. Rather, in some embodiments, such features may be arranged in a different manner and/or order than shown in the illustrative figures. Additionally, the inclusion of a structural or method feature in a particular figure is not meant to imply that such feature is required in all embodiments and, in some embodiments, may not be included or may be combined with other features.

Referring now to FIG. 1, in an illustrative embodiment, an electrical circuit 100 fabricated according to the technologies disclosed herein includes a first semiconductor structure 102, a second semiconductor structure 104, and a nanostructure interconnect 110 extending between the first and second semiconductor structures 102, 104. The nanostructure interconnect 110 is electrically connected to each of the first and second semiconductor structure 102, 104 and electrically connects those structures to each other. Each of the semiconductor structures 102, 104 may be embodied as any type of semiconductor structures including, but not limited to, semiconductor transistors, electrical circuit components, contact pads, other interconnects or conductive elements (e.g., metallization), and/or other semiconductor structures, devices, circuits, connections, or interconnects.

In the embodiment of FIG. 1, the nanostructure interconnect 110 is formed along a generally linear path between the semiconductor structures 102, 104. However, in other embodiments such as the embodiment of FIG. 2, the nanostructure interconnect 110 may be formed along a complex or otherwise non-linear path (e.g., to avoid other electrical components of the electrical circuit 100). Additionally, although the illustrative electrical circuit 100 includes only a single nanostructure interconnect 110 in the embodiments of FIGS. 1 and 2, it should be appreciated that the electrical circuit 100 may include additional nanostructure interconnects 110 in other embodiments.

The illustrative nanostructure interconnect 110 includes an electrically conductive conductor (e.g., a copper conductor) formed in a corresponding nanostructure. For example, as shown in FIG. 3, the illustrative nanostructure interconnect 110 includes an electrically conductive conductor 112 formed in a nanostructure 114. The nanostructure 114 is illustratively embodied as a nanostructure trench (i.e., a “nanotrench”) defined or otherwise formed in a substrate 300. However, in other embodiments, the nanostructure 114 may be embodied as other types of nanostructures formed in the substrate 300 including, but not limited to, a via, a hole, a cavity, or other area or volume of the substrate 300.

Illustratively, the nanostructure interconnect 110 is embodied as a two-dimensional nanostructure in that the nanostructure interconnect 110 includes at least one dimension that is less than 100 nanometers. That is, unlike one-dimensional nanostructures in which two dimensions are on the nanoscale (e.g., less than 100 nanometers) and one is on the microscale or greater, the nanostructure interconnect 110 illustratively includes one dimension on the nanoscale (i.e., less than 100 nanometers) and two dimensions on the microscale or greater (i.e., greater than 100 nanometers). Accordingly, as used herein, a “one-dimensional nanostructure” means a nanostructure in which the size of two dimensions of the nanostructure are on the nanoscale (i.e., less than 100 nanometers) and the remaining one dimension is greater than the nanoscale (i.e., greater than 100 nanometers). Examples of one-dimensional (1D) nanostructures include nanowires, nanorods, nanobelts, and nanotubes-whose lateral dimensions fall anywhere in the range of 1 to 100 nm. Conversely, as used herein, a “two-dimensional nanostructure” means a nanostructure in which the size of one dimension (e.g., the width of a trench) is on the nanoscale (i.e., less than 100 nanometers) and the remaining two dimensions (e.g., the height and length of the trench) are greater than the nanoscale (i.e., each are greater than 100 nanometers). Examples of two-dimensional (2D) nanostructures include nanosheets and deep nanotrenches. In the illustrative embodiment, for example, the nanostructure interconnect 110 (i.e., the nanostructure 114 and the electrically conductive conductor 112) has a width 302 of about 20-40 nanometers and a depth or height 304 of 500-1000 nanometers. As such, depending on the particular dimensions of the width 302 and height 304, the nanostructure interconnect 110 may be fabricated using the technologies disclosed herein to have a height-to-width aspect ratio in the range of 1 to 1,000 or more, including any value therewithin and any subranges therebetween, preferably with a relatively high aspect ratio of at least 5, 10, 15, 20, 25, 30, 35, 40, 45, 50, 100, 150, 200, 250, 300, 350, 400, 450, 500, etc. The overall length of the nanostructure interconnect 110 may depend on various criteria such as the structure or size of the electrical circuit 100, the size of the substrate 300 (e.g., the size of the substrate wafer), and/or other implementation criteria. As such, depending on the overall length of the nanostructure interconnect 110, the nanostructure interconnect 110 may be fabricated using the technologies disclosed herein to have a length-to-width and/or a length-to-height aspect ratio in the range of 1 to 10,000 or more, including any value therewithin and any subranges therebetween, preferably with a relatively high aspect ratio of at least 10, 50, 100, 200, 300, 400, 500, 600, 700, 800, 900, 100, 1,500, 2,000, etc.

As discussed in more detail below, the electrically conductive conductor 112 may be formed from any electrically conductive material suitable to the fabrication techniques described herein. Typically, an electrically conductive material having low resistivity is selected. In the illustrative embodiment, the electrically conductive conductor 112 is embodied as a copper material. However, in other embodiments, the electrically conductive conductor 112 may be embodied as a cobalt or ruthenium material. For example, in some embodiments, the electrically conductive conductor 112 may be embodied as Cobalt Tin (CoSn), Copper Aluminide (AL₂CU), Cobalt Silicide (CoSi), or Molybdenum Phosphide (MoP). Additionally, the electrically conductive conductor 112 may be embodied as a single or polycrystalline material. For example, in the illustrative embodiment, the electrically conductive conductor 112 is embodied as a single copper material or a polycrystalline material.

The substrate 300 may be embodied as any type of substrate in which the nanostructure 114 can be etched, formed, or otherwise established. Typically, a material having a relatively high melting point (i.e., higher than the electrically conductive material forming the electrically conductive conductor 112), low diffusivity, and a high modulus is selected to form the substrate 300. For example, in the illustrative embodiment, the substrate 300 is embodied as a silicon substrate, which may form a portion of a silicon wafer, for example. However, in other embodiments, other types of substrates may be used. For example, the substrate 300 may be embodied as an oxide layer or a dielectric layer, which may be established on another substrate (e.g., on a silicon substrate) using typical semiconductor fabrication techniques. In some embodiments, the substrate 300 may be embodied as MgO substrate, a NaCL substrate, an aluminum oxide (Al₂O₃) layer, or a silicon dioxide (SiO₂) layer. Again, such layers may be formed on other substrates or layers.

In some embodiments, the electrical circuit 100 may also include a barrier layer 120, which may be established (e.g., deposited or grown) over the nanostructure 114 of the nanostructure interconnect 110 and the surrounding substrate 300. The barrier layer 120 may be embodied as any material capable of providing a barrier that limits or otherwise prevents interaction of the electrically conductive conductor 112 and the substrate 300. For example, in embodiments in which the electrically conductive conductor 112 is a copper material, the barrier layer 120 may be formed from a nitride, such as tantalum nitride. However, in other embodiments, the barrier layer 120 may be embodied as, for example, a metallic material, such as silver, lanthanum, titanium, ruthenium iridium, tungsten, zirconium, animony, calcium, or any combination thereof. Alternatively, the barrier layer 120 may be embodied may be embodied as a metal oxide or a metal nitride material. In some embodiments, the barrier layer 120 is embodied as silicon dioxide deepening on, for example, the type of substrate 300 used. Although only a single barrier layer 120 is shown in FIG. 3, it should be appreciated that the electrical circuit 100 may include additional barrier layers in other embodiments and such additional layers may cover common or different areas of the electrical circuit 100 (e.g., one layer may cover the semiconductor structure 102 and another layer may cover the semiconductor structure 104).

Referring now to FIGS. 4-6, in some embodiments, the electrical circuit 100 may be embodied as a vertical electrical circuit with semiconductor structures, devices, or components “buried” in the substrate 300 (e.g., a memory circuit). In such embodiments, the electrical circuit 100 may include multiple nanostructure interconnects 110, each of which may be configured to electrically connect multiple semiconductor structures 102, 104 established in the substrate 300. For example, as shown in FIG. 4, each nanostructure interconnect 110 extends over and electrically connects multiple semiconductor structures 102, 104, which have been previously deposited, grown, or otherwise established in the substrate 300. As shown in FIG. 5, each electrically conductive conductor 112 extends downwardly into the nanostructure 114 (illustratively embodied as a nanotrench) and is electrically connected to a semiconductor structure 102 buried in the substrate 300. In this way, layers of semiconductor devices or circuits can be formed using the nanostructure interconnects 110. As discussed above, the nanostructure interconnects 110 may form lateral or vertical interconnects (e.g., vias), which connect multiple layers of a vertical circuit, in some embodiments. As such, it should be appreciated that the electrical circuit 100 may include multiple levels of nanostructure interconnects 110, which may electrically connect semiconductor structures 102, 104 located on the same level and/or semiconductor structures 102, 104 or other nanostructure interconnects 110 located on other levels (i.e., vertical connectivity) of the electrical circuit 100.

FIG. 6 illustrates a cross-sectional Scanning Transmission Electron Microscopy (STEM) imaging of nanocrystalline copper interconnects formed in corresponding nanostructure (i.e., nanotrenches), which corresponds to the nanostructure interconnects 110 illustrated in FIGS. 4 and 5. A scalebar 600 of 100 nanometers is included to identify the corresponding scale. As shown in FIG. 6, the nanocrystalline copper material has fully or otherwise sufficiently filled the nanotrenches formed in the substrate of that illustrative embodiment.

Referring now to FIGS. 7 and 8, a method 700 may be used to fabricate the electrical circuit 100 and associated nanostructure interconnects 110 described above. The method 700 begins with block 702 in which the substrate 300 is fabricated. As described above, the substrate may be formed from any suitable material such as an oxide or dielectric material (e.g., aluminum oxide (Al₂O₃) or silicon dioxide (SiO₂)). In the illustrative embodiment in block 704, the substrate 300 is fabricated from a silicon material. In such embodiments, the substrate 300 may be embodied as a single substrate as shown in FIG. 9 or may include additional materials, structures, or features depending on the fabrication technique used and the overall process entailed. For example, in some embodiments, multiple layers of silicon may be grown or deposited on each other (or other substrate material) to produce the substrate 300.

Referring back to FIG. 7, after the substrate 300 has been fabricated, the method 700 advances to block 706 in which one or more semiconductor structures 102, 104 are fabricated in the or on the substrate 300. For example, in block 708, one or more semiconductor devices, such as a transistors, may be fabricated using typical semiconductor processing techniques. Additionally or alternatively, in block 710, one or more semiconductor connectors, such as electrical connector pads or connections, may be fabricated on or in the substrate 300. As shown in FIG. 10, in the illustrative embodiment, a semiconductor structure 102 is formed in the substrate 300. The semiconductor structure 102 may be so formed, for example, by ion implantation, deposition, or other fabrication technique. Additionally, in some embodiments, additional semiconductor layers may be formed over the semiconductor structure 102 such that the structure 102 becomes “buried” in the substrate 300.

Referring again back to FIG. 7, after the semiconductor structures 102, 104 have been fabricated in the substrate 300, the method 700 advances to block 712. In block 712, one or more nanostructures 114 are established in the substrate 300. Depending on the particular type of nanostructure 114 to be used, different methodologies may be employed for establishing the nanostructures 114 in the substrate 300. For example, the nanostructures 114 may be formed using an etching process. For example, in an illustrative embodiment, the nanostructure formation process included (1) thermal oxidation for hardmask formation with a 200 nm gap (1 μm pitch), (2) a photolithography process with a KrF scanner (ASML, PAS 5500/700D), (3) hardmask etching (Lam Research, EXELAN-HPT), (4) photoresist stripping (PSK. DAS-2000), (5) post cleaning, (6) silicon trench etching (Lam Research, TCP-9400DFM), (7) another round of post cleaning. (8) hard mask removal through hydrofluoric acid, and (9) low-pressure nitride deposition (Centrotherm, E1200) for gap shrinkage to a target gap of 20˜40 nm. The illustrative etching conditions included a mixture of CF₄, Ar, and O₂ for the Bottom Anti-Reflective Coating (BARC) etching; C₄F₈, Ar, and O₂ for the oxide etching; and He, SF₆, and O₂ gases for silicon trench etching.

In the illustrative embodiment in block 714, the nanostructures 114 are formed as two-dimensional nanostructures. That is, as described above, the nanostructure 114 include at least one dimension less than 100 nanometers, while the other two dimensions may be greater than 100 nanometers. For example, in block 716 and as shown in FIG. 11, the nanostructure 114 may be formed as a nanotrench, which illustrative has a width 302 of about 20-40 nanometers and a depth 304 of about 500-100 nanometers. Additionally, as shown in FIG. 11 and indicated in block 718 of FIG. 7, the nanostructure(s) 114 are established or formed in the substrate 300 so as to connect multiple semiconductor structures 102, 104. That is, the nanostructure 114 (e.g., a nanotrench) is exposed to the corresponding semiconductor structures 102, 104 such that the electrically conductive conductor 112 that is subsequently molded into the nanostructure 114 can electrically contact the corresponding semiconductor structures 102, 104.

After the semiconductor structures 102, 104 have been formed in the substrate 300, the method 700 advances to block 720 in some embodiments. In block 720, a barrier liner layer 120 is deposited or otherwise formed over the nanostructures 114 as illustrated in FIG. 12. As discussed above, the barrier liner layer 120 may be embodied as any material capable of providing a barrier that limits or otherwise prevents interaction of the electrically conductive conductor 112 and the substrate 300. For example, the barrier layer 120 may be embodied as silicon dioxide, a metal oxide, a metal nitride, or other metallic material. The barrier layer 120 may be formed in/over the nanostructure 114 (and surrounding substrate 300 in some embodiments) using any suitable fabrication techniques such as a deposition process (e.g., a chemical vapor deposition process) or growth process (e.g., an epitaxial growth process).

FIGS. 13 and 14 illustrate a cross-sectional Scanning Transmission Electron Microscopy (STEM) imaging of set of trench nanostructures 114 formed in a substrate 300 and including a barrier liner layer 120 formed over the nanostructures 114. A scalebar 1300 of 1 micrometer (1 μm) is included in FIG. 13, and a scalebar 1400 of 1 nanometer is included in FIG. 14 to identify the corresponding scales.

Referring now back to FIG. 7, after the nanostructures 114 have been established in block 712 and the barrier layer 120, if any, has been formed in block 720, the method 700 advances to block 722. In block 722, an electrically conductive material is established over the nanostructures 114. As shown in FIG. 15, the electrically conductive material may be embodied as an electrically conductive material layer 1550, which may be overlaid, deposited, grown, or otherwise formed over the nanostructures 114 (and surrounding substrate 300) using any suitable methodology to form a semiconductor assembly 1500. For example, in some embodiments, the electrically conductive material layer 1550 is embodied as a foil layer of electrically conductive material (e.g., copper), which is placed over the nanostructure 114. In other embodiments, the electrically conductive material layer 1550 is grown as a thin film on the substrate 300.

As discussed above, the electrically conductive material (which subsequently forms the electrically conductive conductor 112) may be embodied as any electrically conductive material feedstock that is suitable to the fabrication techniques described herein such as, for example, copper, cobalt, ruthenium, CoSn, AL₂CU, CoSi, or MoP. Additionally, as discussed above, the electrically conductive material may be polycrystalline or single crystal material. For example, in block 724 of FIG. 7, a nanocrystalline copper feedstock may be used as the electrically conductive material, which may have grain sizes from 50 nanometers to 7 micrometers. Alternatively, in block 726, a micocrystalline copper feedstock may be used as the electrically conductive material, which may have gain sizes from 1 micrometer to 50 micrometers.

Furthermore, in the illustrative embodiment in block 728, a single crystal copper feedstock is used as the electrically conductive material. In doing so, it has been determined that the success of nanomolding the single crystal copper feedstock is dependent on the orientation of the single crystal with respect to the inner walls of the nanotrench. If the single crystal copper feedstock is not properly orientated, substantially higher pressure may be required to achieve nanomolding, which can crack or damage the substrate 300. As such, the single crystal copper feedstock may be aligned to a trench wall in block 730 to improve the nanomolding of the single crystal copper feedstock.

To align the feedstock to the nanotrench, a crystallographic plane of the electrically conductive material layer 1550 that has the lowest surface energy parallel is aligned to the inner wall of the nanotrench. For example, as shown in FIG. 16, a single crystal copper foil layer 1550 is aligned such that the (111) crystallographic plane of the single crystal copper material is parallel to a longitudinal inner wall 1600 of the trench nanostructure 114. It should be appreciated that once the foil layer 1550 is properly aligned to a single trench nanostructure 114, that foil layer 1550 is also aligned with other trench nanostructures 114 parallel to that aligned trench nanostructure 114. Proper alignment of the layer 1550 may be confirmed via Laue diffraction. It should be appreciated that the described alignment process is usable for other Face Centered Cubic (FCC) single crystal structures, in addition to copper. For Body Centered Cubic (BCC) single crystal structures, the (110) crystallographic plane may be aligned to the longitudinal inner wall 1600 of the trench nanostructure 114. For Hexagonal Close Packed (HCP) single crystal structures, the (001) crystallographic plane may be aligned to the longitudinal inner wall 1600 of the trench nanostructure 114. In embodiments, in which the electrically conductive material layer 1550 is grown on the substrate 300, the electrically conductive material layer 1550 may be aligned with the inner wall 1600 of the trench nanostructure 114 via the growth process.

For polycrystalline layers 1550, it has been determined that the crystal will slowly rotate toward an orientation in which the lowest surface energy parallel is aligned to the inner wall of the nanotrench. However, such rotation takes place over distances longer than the depth of the corresponding trench nanostructure 114 (e.g., >500 nanometers). As such, the resulting material located in the trench nanostructure 114 after thermal processing (see description of block 732 of method 700 below), will also be polycrystalline but with defects, such as twins. The use of a single crystal feedstock reduces grain rotation and increases the likelihood of single crystal formation along the length of the trench nanostructure 114. For example, FIG. 18 illustrates a 4D-STEM grain orientation map of nanocrystalline copper interconnects formed in corresponding nanostructure trenches subsequent to a thermal process as described above. Conversely, FIG. 19 illustrates a single crystal copper interconnect formed in a corresponding nanostructure trench and having the (111) crystallographic plane of the single crystal copper interconnect aligned with an inner wall of the trench.

Referring back to FIG. 7, after the electrically conductive material 1550 has been established over the corresponding nanostructure 114 in block 722, the method 700 advances to block 732 of FIG. 8. In block 732, a thermal process is performed on the semiconductor assembly 1500 (i.e., the substrate 300 and the electrically conductive material layer 1550) to mold the electrically conductive material layer 1550 into the corresponding nanostructure 114 to form the electrically conductive conductor 112 therein as shown in FIG. 17. To do so, in block 734 of FIG. 8, a thermal process having a pressure, temperature, and process time based on the type of electrical conductive material is performed. For example, the thermal process may include heating the semiconductor assembly 1500 to a melting temperature (Tm) of the electrically conductive material 1550 in the range of 0.4 Tm to 0.7 Tm at a pressure in the range of 20 MegaPascals (MPa) to 100 MPa for a time period in the range of 1 hour to 2 hours. More specifically, if the electrically conductive material 1550 is embodied as a nanocrystalline copper material, the thermal process may include heating the semiconductor assembly 1500 to a temperature of about 400 degrees Celsius at a pressure of about 30 MPa for a time period of about 90 minutes. Alternatively, if the electrically conductive material 1550 is embodied as a microcrystalline copper material, the thermal process may include heating the semiconductor assembly 1500 to a temperature of about 400 degrees Celsius at a pressure of about 60 MPa for a time period of about 90 minutes. Further, if the electrically conductive material 1550 is embodied as a microcrystalline copper material, the thermal process may include heating the semiconductor assembly 1500 to a temperature of about 400 degrees Celsius at a pressure of about 70 MPa for a time period of about 90 minutes. Higher temperatures and pressures may be used in some embodiments; however, high temperatures and pressures increase the risk heat damage and fracturing of the semiconductor assembly 1500 in other areas. The thermal process may be achieved using various heating equipment and processes. For example, in some embodiments a hot press, in which a press is encapsulated by a corresponding furnace, may be used. In other embodiments, the heating process may be achieved via heating the anvils that are apply pressure to the semiconductor assembly 1500, which conducts heat to the electrically conductive material 1550 during loading. Alternatively, in other embodiments, a laser may be used to selectively heat the semiconductor assembly 1500.

Referring back to FIG. 8, after the thermal process has been performed on the semiconductor assembly 1500, the method 700 advances to block 736 in which final or additional processing of the semiconductor assembly 1500 is performed. For example, in block 738, any electrically conductive material 1550 remaining on top of the substrate 300 may be etched or otherwise removed. Additionally, in some embodiments, the substrate 300 may be further etched away to form freestanding nanostructures. For example, FIG. 20 illustrates a “false color” SEM image of a set of single crystal copper nanofins, which may be formed via the etching process of block 738. A scalebar 2000 of 2 micrometers is included to identify the corresponding scale.

Referring now to FIGS. 21-23, imaging illustrations of an electrical circuit 100 including nanocrystalline copper nanostructure interconnects 110 fabricated according to the method 700 described above are shown. FIG. 21 illustrates an illustrative Optical Bright Field Image of a set of nanocrystalline copper nanostructure interconnects 110. A scalebar 2100 of 10 micrometers is included to identify the corresponding scale. FIG. 22 illustrates a cross-sectional SEM imaging of the nanocrystalline copper nanostructure interconnects 110 of FIG. 21. A scalebar 2200 of 1 micrometers is included to identify the corresponding scale. FIG. 23 illustrates a longitudinal cross-sectional SEM imaging of the nanocrystalline copper nanostructure interconnects 110 of FIG. 21. A scalebar 2300 of 1 micrometers is included to identify the corresponding scale. As shown in each of FIGS. 21-23, the nanocrystalline copper conductive material has substantially filled the corresponding nanotrenches.

Similarly, FIG. 24 illustrates a longitudinal cross-sectional SEM imaging of a microcrystalline copper nanostructure interconnect 110 formed in a corresponding nanotrench using the method 700 described above. A scalebar 2400 of 2 micrometers is included to identify the corresponding scale. Additionally, FIG. 25 illustrates a cross-sectional STEM imaging of a set of single crystal copper interconnects 110 formed in corresponding nanotrenches according to the method 700 described above. A scalebar 2500 of 1 micrometers is included to identify the corresponding scale. Again, as shown in each of FIGS. 24 and 26, the microcrystalline copper conductive material of FIG. 24 and the single crystal copper material of FIG. 25 have sustainably filled the corresponding nanotrenches.

While the disclosure has been illustrated and described in detail in the drawings and foregoing description, such an illustration and description is to be considered as illustrative and not restrictive in character, it being understood that only illustrative embodiments have been shown and described and that all changes and modifications that come within the spirit of the disclosure are desired to be protected.

There are a plurality of advantages of the present disclosure arising from the various features of the methods, apparatuses, and systems described herein. It will be noted that alternative embodiments of the methods, apparatuses, and systems of the present disclosure may not include all of the features described yet still benefit from at least some of the advantages of such features. Those of ordinary skill in the art may readily devise their own implementations of the methods, apparatuses, and systems that incorporate one or more of the features of the present invention and fall within the spirit and scope of the present disclosure as defined by the appended claims.

1. A method for forming semiconductor interconnects, the method comprising:
establishing a nanostructure in a substrate, wherein the nanostructure extends from a first semiconductor structure of the substrate to a second semiconductor structure of the substrate;
establishing an electrically conductive material on the substrate over the nanostructure to form a semiconductor assembly; and
performing a thermal process on the semiconductor assembly that causes the electrically conductive material to mold into the nanostructure established in the substrate to form an electrical interconnect that electrically connects the first semiconductor structure to the second semiconductor structure.

2. The method of claim 1, wherein the nanostructure comprises a trench formed in the substrate.

3. The method of claim 2, wherein the trench has at least one dimension that is less than 100 nanometers.

4. The method of claim 3, wherein the trench has an aspect ratio of a height of the trench to a width of the trench of at least 10.

5. The method of claim 1, wherein establishing the nanostructure in the substrate comprises establishing the nanostructure in a silicon substrate, an oxide layer, or a dielectric layer.

6. The method of claim 1, wherein the first semiconductor structure comprises a first semiconductor transistor and the second semiconductor structure comprises a second semiconductor transistor, and
wherein establishing the nanostructure in the substrate comprises establishing the nanostructure to extend from the first semiconductor transistor to the second semiconductor transistor.

7. The method of claim 1, wherein establishing the electrically conductive material on the substrate over the nanostructure comprises establishing a single crystal copper layer on the substrate over the nanostructure.

8. The method of claim 1, wherein establishing the electrically conductive material on the substrate over the nanostructure comprises establishing a polycrystalline copper layer on the substrate over the nanostructure.

9. The method of claim 1, wherein the nanostructure comprises a trench formed in the substrate, wherein the trench includes an inner wall, and
wherein establishing the electrically conductive material on the substrate comprises aligning the electrically conductive material with the inner wall of the trench.

10. The method of claim 9, wherein aligning the electrically conductive material with the inner wall of the trench comprises aligning a crystallographic plane of the electrically conductive material that has the lowest surface energy parallel to the inner wall of the trench.

11. The method of claim 9, wherein the electrically conductive material comprises a single crystal copper material, and
wherein aligning the electrically conductive material with the inner wall of the trench comprises aligning the (111) crystallographic plane of the single crystal copper material parallel to the inner wall of the trench.

12. The method of claim 9, wherein the electrically conductive material comprises a Body Centered Cubic (BCC) structured material, and
wherein aligning the electrically conductive material with the inner wall of the trench comprises aligning the (110) crystallographic plane of the BCC structured material parallel to the inner wall of the trench.

13. The method of claim 9, wherein the electrically conductive material comprises a Hexagonal Close Packed (HCP) structured material, and
wherein aligning the electrically conductive material with the inner wall of the trench comprises aligning the (001) crystallographic plane of the HCP structured material parallel to the inner wall of the trench.

14. The method of claim 1, wherein performing the thermal process comprises heating the semiconductor assembly to a melting temperature (Tm) of the electrically conductive material of in the range of 0.4 Tm to 0.7 Tm at a pressure in the range of 20 MegaPascals (MPa) to 100 MPa for a time period in the range of 1 hour to 2 hours.

15. The method of claim 14, wherein the electrically conductive material comprises a nanocrystalline copper material, and
wherein performing the thermal process comprises heating the semiconductor assembly to a temperature of 400 degrees Celsius at a pressure of 30 MPa for a time period of about 90 minutes.

16. The method of claim 14, wherein the electrically conductive material comprises a microcrystalline copper material, and
wherein performing the thermal process comprises heating the semiconductor assembly to a temperature of 400 degrees Celsius at a pressure of 60 MPa for a time period of about 90 minutes.

17. The method of claim 14, wherein the electrically conductive material comprises a single crystal copper material, and
wherein performing the thermal process comprises heating the semiconductor assembly to a temperature of 400 degrees Celsius at a pressure of 70 MPa for a time period of about 90 minutes.

18. The method of claim 1, further comprising lining the nanostructure with a barrier material prior to establishing the electrically conductive material on the substrate, wherein the barrier material limits interaction of the electrically conductive material and the substrate.

19. An electrical circuit comprising:
a first semiconductor device established in a substrate;
a second semiconductor device established in the substrate; and
a two-dimensional nanostructure interconnect that electrically connects the first semiconductor device to the second semiconductor device.

20. The electrical circuit of claim 19, wherein the two-dimensional nanostructure interconnect consists of a single crystal copper interconnect formed in a trench of the substrate having a width less than 100 nanometers and an aspect ratio of a height of the trench to the width of the trench of at least 10.
